(19) United States
(12) Patent Application Publication
(10) Pub. No.: US 2006/0109624 A1
(43) Pub. Date: May 25, 2006

(54) Side-suction heat dissipating structure for an industrial computer

(76) Inventor: Kuo-Chuan Hung, Lu-Chou City (TW)

Correspondence Address: Kuo-Chuan HUNG, P.O. Box No. 6-57, Junghe, Taipei, 235, TW

(21) Appl. No.: 10/991,390

(22) Filed: Nov. 19, 2004

(51) Int. Cl. H05K 7/20

(52) U.S. Cl. 361/694

(57) ABSTRACT

A side-suction heat dissipating structure for an industrial computer comprises primarily a wind shade, fins, and fans to quickly expel heat generated by a CPU inside of an industrial computer, preventing from the impact to overall efficiency by the accumulation of heat. The features include that a motherboard is rotated by 90 degrees counter-clockwise and fixed inside a computer casing, that fins are emplaced inside a wind shade such that the bottom of fins can be tightly attached to the top of CPU enabling the alignment of heat flow inside the computer casing with the direction of overall heat dissipating, and reducing the distance from CPU to the back panel of the computer casing, thereby improving the efficiency of heat dissipation.

### BACKGROUND OF THE INVENTION

a) Field of the Invention

The present invention relates to a side-suction heat dissipating structure for an industrial computer, and more particularly to a structure wherein a motherboard is rotated by 90 degrees counter-clockwise, to minimize the distance from a CPU (Central Processing Unit) to the rear part of the computer casing, and align with the direction of overall heat dissipation, thereby improving the efficiency of heat dissipation.

b) Description of the Prior Art

As a CPU of an industrial computer usually consumes higher power, the CPU also generates the most heat. Because the built-in space for heat dissipation inside a computer casing is limited, and conventionally, the heat dissipation space for an industrial server is smaller than that of a desktop computer, hence a variety of configuration are used for the structure of heat dissipation. In general, as shown in FIG. 1, a heat dissipater b is emplaced on the top of a heat source a to conduct the heat generated by the heat source to the heat dissipater b, and a fan c is used to dissipate the heat and expel through a rear vent d. This kind of heat dissipation configuration can achieve the function of heat dissipation, however, due to that the heat source is entirely confined in a heat dissipater with limited heat dissipation area in a short time, and accumulates continuously, it is not very easy to expel heat within a short time; besides, due to that this kind of heat dissipater requires very long time to achieve the function of heat dissipation, this kind of heat dissipation is not perfect.

Accordingly, the present invention comprises a fan at the rear part of a computer casing, and a wind shade that can cover fins, such that the bottom of fins can be tightly attached to the top of a CPU. Moreover, with the design of outward suction of fans at the back panel, and the close proximity of the CPU to the rear vent, the fans at the back panel can quickly expel the heat generated by the CPU out of the casing. In addition, due to the alignment of the direction of heat dissipation with the configuration inside the casing, heat generated by other heating elements inside the casing can also be expelled out, thereby greatly improving the efficiency of heat dissipation.

### SUMMARY OF THE INVENTION

The primary object of the present invention is to provide a heat dissipation structure inside an industrial computer, with a simple design and ability to improve the efficiency of heat dissipation.

Accordingly, the present invention comprises primarily a wind shade, fins, and fans, wherein, an indented gap is formed at the rear part of one side of a computer casing for providing for an input/output connecting interface, a motherboard is rotated by 90 degrees counter-clockwise and fixed inside the casing, and fins are emplaced inside the wind shade after latching the input/output connecting interface into a hole site, such that the bottom of fins can be tightly attached to the top of CPU; then, the wind shade is connected to the back panel of the casing to contain several fans in the interior space of the connecting place of the wind shade and the casing, thereby dissipating heat in an outward suction way.

Accordingly, a CPU that is originally located at the center will be moved backward to be closer to the back panel of the casing, therefore, the distance between the fans and the CPU will be reduced, and, correspondingly, the distance of heat suction inside the wind shade is also reduced, thereby increasing the strength of suction force; moreover, as the fins are inside the wind shade with an inward opening, when the rear fans start to expel heat, a kind of ventilation function can be generated, which can also expel heat generated by several heating elements on the motherboard, thereby achieving the object of improving the efficiency of heat dissipation. In addition, using several fans can greatly increase the suction force without the effect that the overall function of heat dissipation is lost when one of the fans fails, because when one of the fans fails, the rest of the fans can be still functioning, to achieve the object of dissipating heat continuously.

To enable a further understanding of the said objectives and the technological methods of the invention herein, the brief description of the drawings below is followed by the detailed description of the preferred embodiments.

### BRIEF DESCRIPTION OF THE DRAWINGS

FIG. 1 shows a schematic view of a conventional heat dissipation structure.

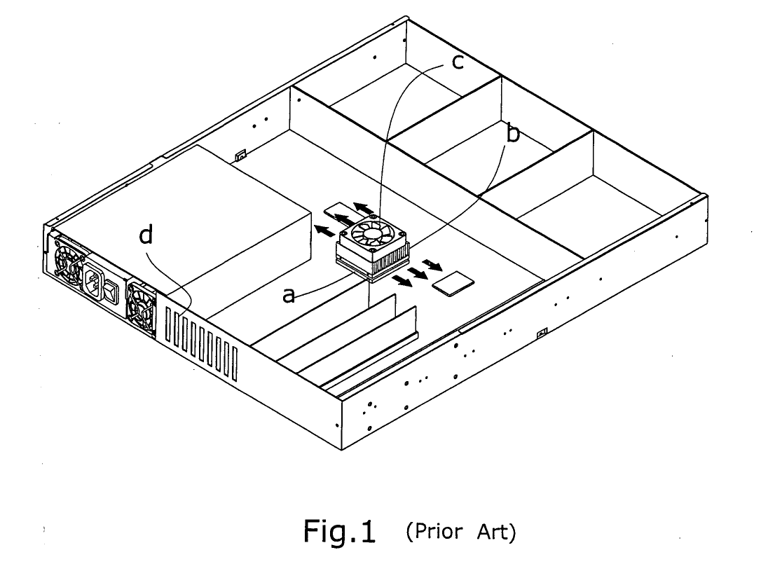

FIG. 2 shows composing parts of the present invention.

FIG. 3 shows structure of the present invention.

FIG. 4A shows a schematic view of the implementation for the present invention.

FIG. 4B shows a side profile of the present invention.

### DETAILED DESCRIPTION OF THE PREFERRED EMBODIMENTS

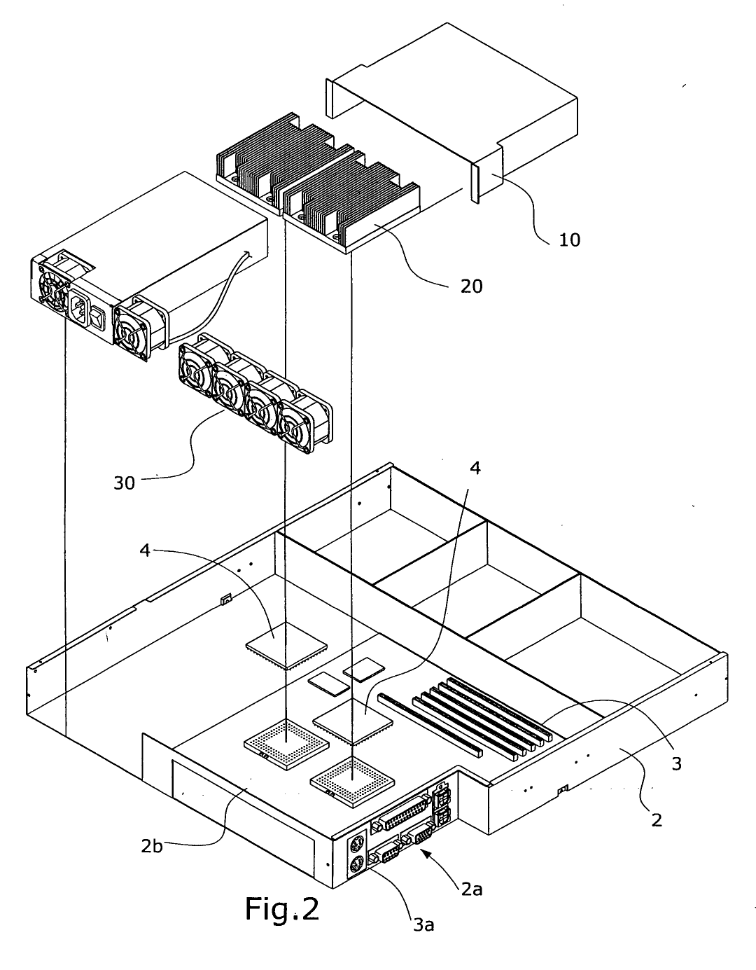

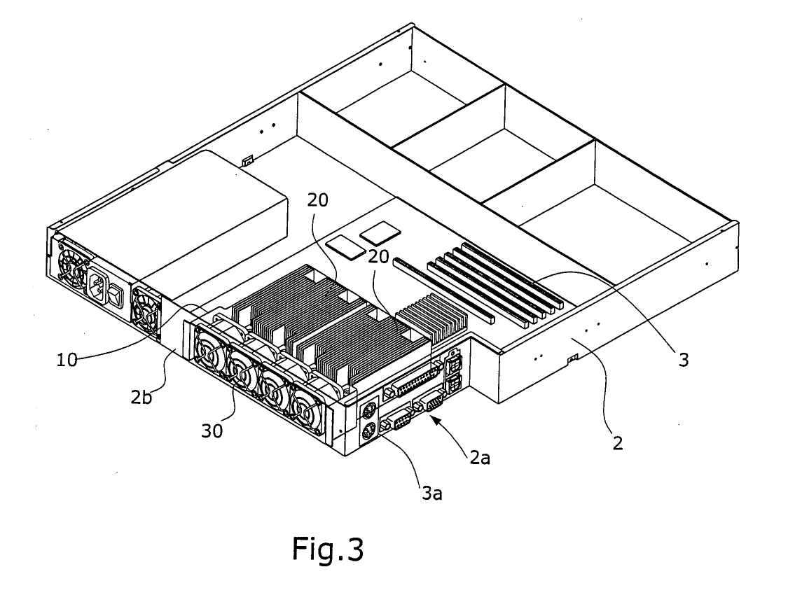

Referring to FIG. 2 and FIG. 3, the present invention comprises primarily a wind shade 10, fins 20, and several fans 30, wherein, an indented gap 2a is formed at the rear part of one side of a computer casing 2 for providing for an input/output connecting interface 3a on a motherboard 3, the motherboard 3 is rotated by 90 degrees counter-clockwise and fixed inside the casing 2, the input/output connecting interface 3a on the motherboard 3 passes through the indented gap 2a, and fins 20 are emplaced inside the wind shade 10, such that the bottom of fins 20 can be tightly attached to the top of CPU 4; then, the wind shade 10 is connected to the back panel 2b of the casing 2 to contain several fans 30 in the interior space of the connecting place, thereby dissipating heat in an outward suction way.

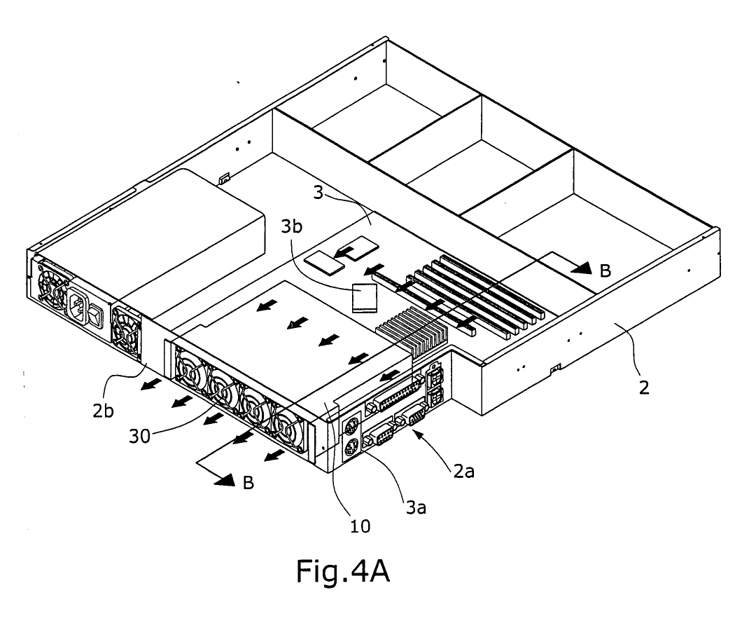

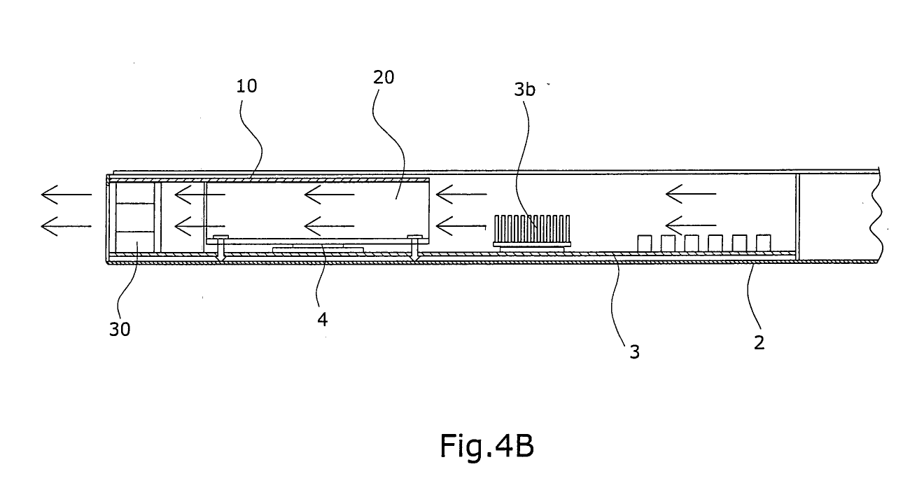

Referring to FIG. 4A and FIG. 4B, which show two schematic views of the implementation for the present invention, a CPU 4 will be moved backward to be closer to a back panel 2b of a computer casing 2, therefore, the distance between fans 30 and the CPU 4 will be reduced; moreover, as fins 20 are inside a wind shade 10 with an inward opening, when the rear fans 30 start to expel heat, a kind of ventilation function can be generated, which can also expel out heat generated by several heating elements 3b on a motherboard 3.

It is of course to be understood that the embodiments described herein is merely illustrative of the principles of the invention and that a wide variety of modifications thereto may be effected by persons skilled in the art without departing from the spirit and scope of the invention as set forth in the following claims.

What is claimed is:

1. A side-suction heat dissipating structure for an industrial computer, mainly comprising a wind shade, fins, and fans, that can quickly expel heat generated by a CPU inside of the industrial computer to prevent from the impact to overall efficiency by the accumulation of heat, including the following features that a motherboard is rotated by 90 degrees counter-clockwise and fixed inside a computer casing, that an input/output connecting interface on the motherboard passes through an indented gap at the rear part of one side of the computer casing, that fins are emplaced inside a wind shade such that the bottom of fins can be tightly attached to the top of CPU, and that several fans are emplaced inside the interior space of the connecting place of the computer casing and the wind shade, thereby improving the efficiency of heat dissipation.

2. The side-suction heat dissipating structure of an industrial computer according to claim 1, wherein an outward suction way is used for the fans.
